(19) United States
(12) Patent Application Publication
(10) Pub. No.: US 2025/0107211 A1
(43) Pub. Date: Mar. 27, 2025

(54) HYBRID CHANNEL POWER SEMICONDUCTOR DEVICE AND METHOD FOR MANUFACTURING SAME

(71) Applicant: Microchip Technology Incorporated, Chandler, AZ (US)

(72) Inventors: Shesh Mani Pandey, Gilbert, AZ (US); Randy L. Yach, Phoenix, AZ (US); Bruce Odekirk, Portland, OR (US)

(73) Assignee: Microchip Technology Incorporated, Chandler, AZ (US)

(21) Appl. No.: 18/891,966

(22) Filed: Sep. 20, 2024

Related U.S. Application Data
(60) Provisional application No. 63/539,743, filed on Sep. 21, 2023.

(51) Int. Cl. H01L 29/49; H01L 29/06; H01L 29/08; H01L 29/808

(52) U.S. Cl. CPC H10D 64/671; H10D 30/83; H10D 62/114; H10D 62/151; H10D 64/661

(57) ABSTRACT

A semiconductor device is provided. The semiconductor device may include a silicon carbide substrate, a silicon layer formed at a first side of the silicon carbide substrate, a gate oxide layer formed on the silicon layer, a gate terminal formed on the gate oxide layer, a drain terminal formed at a second side of the silicon carbide substrate opposite the first side, and a source terminal formed at the first side of the silicon carbide substrate, and at opposite ends of the silicon layer.

### CROSS-REFERENCE TO RELATED APPLICATION

The present application claims priority to U.S. Provisional Patent Application No. 63/539,743, entitled: Hybrid Channel Power Semiconductor Device and Method for Manufacturing Same, filed on Sep. 21, 2023, the contents of which are hereby incorporated by reference in their entirety.

### TECHNICAL FIELD

The present disclosure relates generally to power semiconductor devices, and more specifically to a power semiconductor device having a hybrid channel that includes silicon carbide and silicon.

### SUMMARY

According to an aspect of one or more examples, there is provided a semiconductor device that may include a silicon carbide substrate, a silicon layer formed at a first side of the silicon carbide substrate, a gate oxide layer formed on the silicon layer, a gate terminal formed on the gate oxide layer, a drain terminal formed at a second side of the silicon carbide substrate opposite the first side, and a source terminal formed at the first side of the silicon carbide substrate, and at opposite ends of the silicon layer. The silicon carbide substrate may be made of n-type silicon carbide. The source terminal may be made of n-type silicon. The n-type silicon of the source terminal may be more heavily doped than the n-type silicon carbide of the silicon carbide substrate. The source terminal may at least partially overlap with the gate terminal. The gate oxide layer may have a thickness that is less than a thickness of the silicon layer. The drain terminal may be made of n-type silicon carbide. The n-type silicon carbide of the drain terminal may be more heavily doped than the n-type silicon carbide of the silicon carbide substrate. The semiconductor device may also include first and second p-well regions disposed in the silicon carbide substrate at opposite ends of the silicon layer, and first and second P+ regions within the first and second p-well regions, respectively. The source terminal may be formed within the first and second p-well regions. The first and second p-well regions may be made of p-type silicon carbide. The first and second P+ regions may be made of p-type silicon. The semiconductor device may also include a polysilicon layer on the gate oxide layer. The gate terminal may be formed on the polysilicon layer.

According to an aspect of one or more examples, there is provided method of manufacturing a semiconductor device. The method may include forming a first N+ region at one side of a silicon carbide substrate for a drain terminal of the semiconductor device, forming a silicon layer at an opposite side of the silicon carbide substrate that is opposite from the side at which the first N+ region is formed, forming a gate oxide layer on the silicon layer, and a gate terminal on the gate oxide layer, and forming second and third N+ regions on opposite sides of the silicon layer to form a source terminal. The method may also include forming first and second p-well regions in the silicon carbide substrate at opposite ends of the silicon layer, and forming first and second P+ regions within the first and second p-well regions. The second and third N+ regions may be respectively formed within the first and second p-well regions. The first and second p-well regions may be made of p-type silicon carbide, and the second and third N+ regions may be made of n-type silicon. The first N+ region may be made of n-type silicon carbide. The method may also include forming a polysilicon layer on the gate oxide layer. The gate terminal may be formed on the polysilicon layer. The second and third N+ regions may at least partially overlap the gate oxide layer. A portion of the silicon carbide substrate may extend between the first and second p-well regions.

### BRIEF DESCRIPTION OF DRAWINGS

FIG. 1 shows a semiconductor device according to one or more examples.

FIGS. 2A through 2F show a method of manufacturing the semiconductor device of FIG. 1 according to various examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

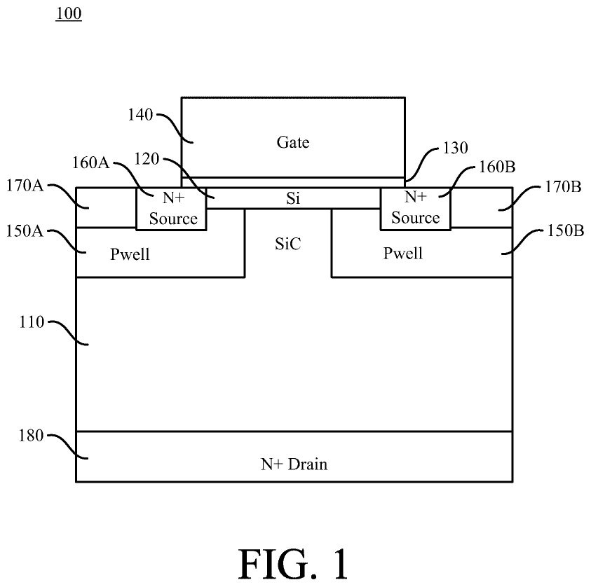

FIG. 1 shows a semiconductor device 100 according to one or more examples. The semiconductor device 100 shown in FIG. 1 may include a silicon carbide (SiC) substrate 110. Silicon carbide is often used as a substrate to create many semiconductor devices, and may result in reduced switching losses, higher power density, improved heat dissipation, and increased bandwidth as compared with other materials. Some semiconductor devices, such as metal-oxide-semiconductor field-effect transistors (MOSFETs) include a gate oxide layer that is a dielectric layer that separates the silicon carbide substrate from a gate electrode, which may be made of metal or other conductive material.

When forming the gate oxide layer on a silicon carbide substrate, the interface between the silicon carbide substrate and the gate oxide layer (for example, a gate oxide layer made of silicon dioxide) may be very rough. The rough interface between the gate oxide layer and the silicon carbide substrate may degrade carrier mobility in the silicon carbide substrate, which may limit device performance. Referring back to FIG. 1, a layer of silicon (Si) 120 may be grown or deposited at a first side of the silicon carbide (SiC) substrate 110. For example, as shown in FIG. 1, the silicon layer 120 is formed at a first side (top side in the example of FIG. 1) of the silicon carbide substrate 110. According to one or more examples, the silicon layer 120 may be approximately 100 Å to 500 Å thick, though other thicknesses may be used depending on the application. For example, the amount of silicon used to create the silicon layer 120 may depend on the thickness of the gate oxide layer 130 to be formed on the silicon layer 120. As shown in FIG. 1, a gate oxide layer 130 may be formed on the silicon layer 120. For example, the gate oxide layer 130 may be a layer of silicon dioxide (SiO₂), which may be formed or grown by a thermal oxidation process of the silicon layer 120. A poly-silicon layer 140 may be formed on the gate oxide layer 130, which will ultimately form the gate terminal of the semiconductor device 100. For example, the gate terminal may be formed of metal, polysilicon, or other suitable material.

The semiconductor device of FIG. 1 may include two p-wells 150A and 150B that are formed within the silicon carbide substrate 110 at opposite ends of the silicon layer 120, and are located on either side of the gate terminal. As shown in FIG. 1, the p-wells 150A and 150B may partially overlap underneath the gate terminal, and may be made of p-type silicon carbide. A source terminal may be formed at the first side of the silicon carbide substrate 110, and at opposite ends of the silicon layer 120. For example, as shown in FIG. 1, the source terminal may be formed by forming two N+ regions 160A and 160B within the respective p-wells 150A and 150B. For example, N+ region 160A may be formed within p-well 150A, and N+ region 160B may be formed within p-well 150B. The two N+ regions 160A and 160B may be made of n-type silicon that is more heavily doped than the n-type silicon carbide substrate 110. The gate terminal and the gate oxide layer 130 may extend to at least partially overlap the two N+ regions 160A and 160B. The semiconductor device 100 shown in FIG. 1 may also include a body terminal formed of two P+ regions 170A and 170B formed within the respective two p-wells 150A and 150B. For example, P+ region 170A may be formed within p-well 150A, and P+ region 170B may be formed within p-well 150B. The two P+ regions 170A and 170B may be formed of p-type silicon and may be more heavily doped than the p-wells 150A and 150B. The two P+ regions 170A and 170B may be located adjacent to the respective N+ regions 160A and 160B. For example, P+ region 170A is located adjacent to N+ region 160A, and P+ region 170B is located adjacent to N+ region 160B. The semiconductor device 100 may also include N+ region 180, which will ultimately form the drain terminal of the semiconductor device 100. The drain terminal may be formed at a second side of the silicon carbide substrate 110 opposite the first side. For example, as shown in FIG. 1, the drain terminal is located at a bottom side of the silicon carbide substrate 110. The drain terminal may be made of N+ region 180, which may be made of n-type silicon carbide, and may be more heavily doped than the n-type silicon carbide of the silicon carbide substrate 110.

In operation, when a positive voltage is applied to the gate terminal, an n-type channel is formed from the two N+ regions 160A and 160B that comprise the source terminal, through the silicon layer 120 and the silicon carbide substrate 110, to the drain terminal. The silicon layer 120 may form a smoother interface with the gate oxide layer 130 than the silicon carbide substrate 110 would form with the gate oxide layer 130, which may improve carrier mobility. This hybrid channel that includes silicon and silicon carbide may provide for increased carrier mobility, and potential benefits of the silicon carbide substrate 110 such as reduced switching losses, higher power density, improved heat dissipation, and increased bandwidth.

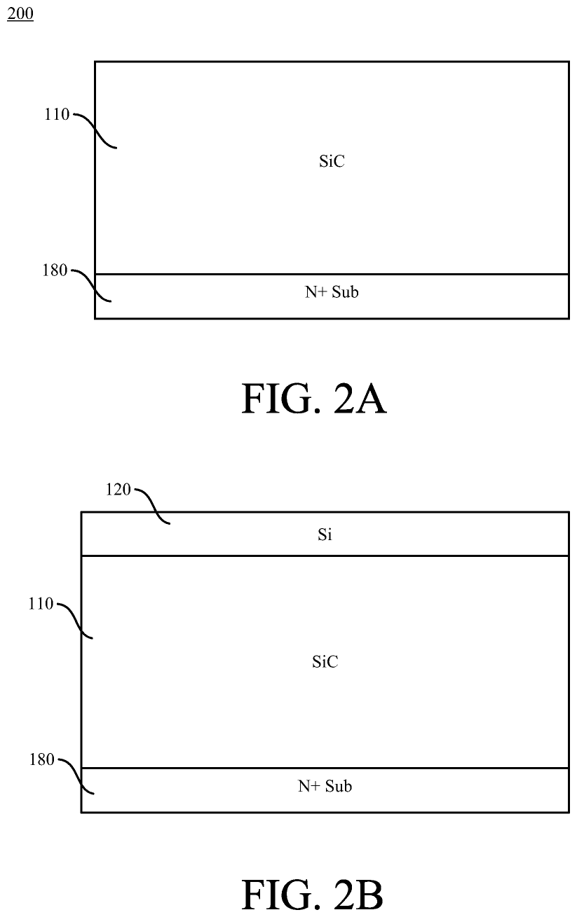

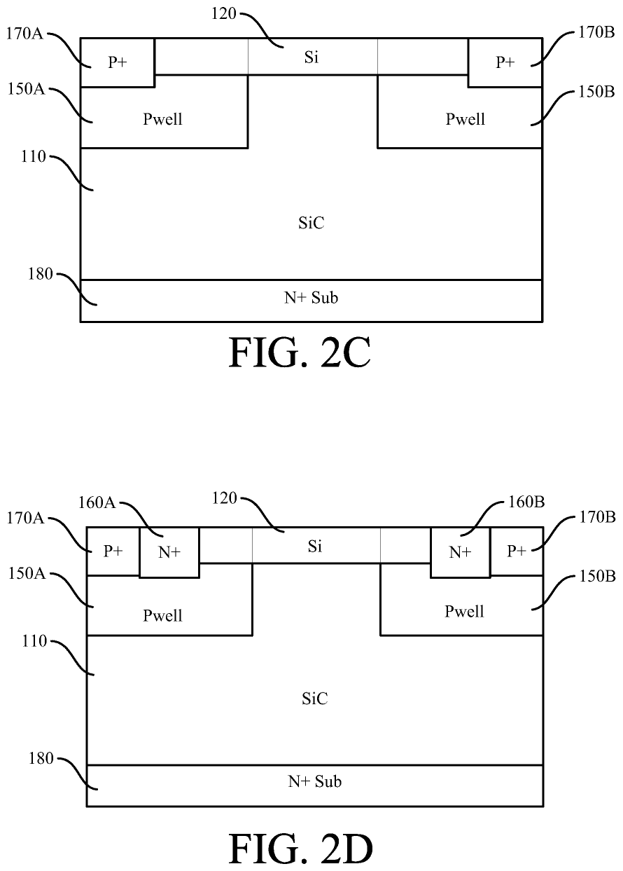

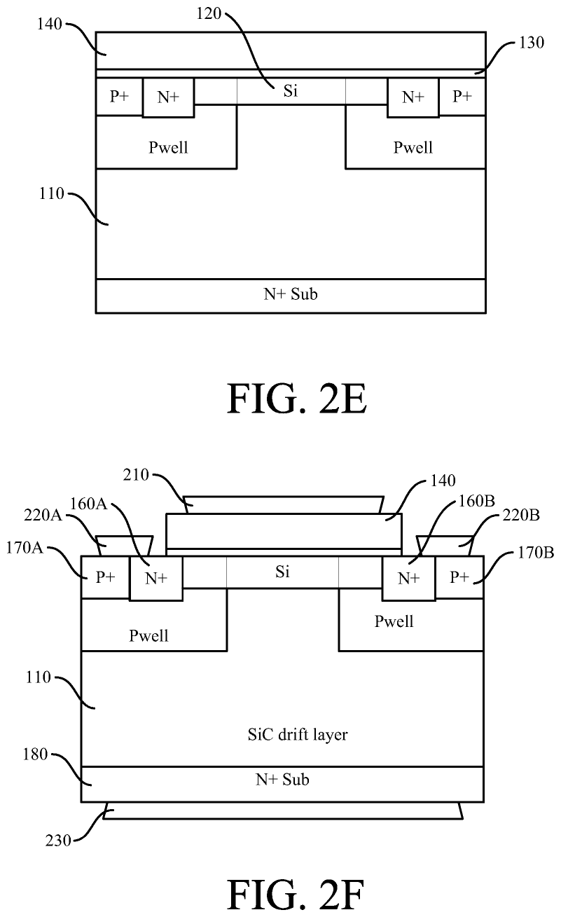

FIGS. 2A through 2F show a method 200 of manufacturing the semiconductor device 100 of FIG. 1.

In FIG. 2A, the method 200 may begin with a silicon carbide substrate 110, which in the example shown in FIG. 2A is made of n-type silicon carbide. A more heavily doped n-type (N+) region 180 of silicon carbon may be formed at one side of the silicon carbide substrate 110, which will ultimately be a drain terminal of the semiconductor device 100.

FIG. 2B shows an operation of forming a silicon layer 120 on the silicon carbide substrate 110. The silicon layer 120 may be formed on a side of the silicon carbide substrate 110 that is opposite the side on which the N+ region 180 is formed. The silicon layer 120 may be implanted in the silicon carbide substrate 110. According to one or more examples, the silicon layer 120 may be formed by bonding a silicon wafer to the silicon carbide substrate 110.

FIG. 2C shows an operation of forming two P-well regions 150A and 150B at two lateral ends of the silicon carbide substrate 110. The two P-well regions 150A and 150B may be made of p-type silicon carbide. As shown in FIG. 2C, two more heavily doped p-type (P+) regions 170A and 170B may be implanted in the respective P-wells 150A and 150B. For example, P+ region 170A may be implanted in P-well 150A, and P+ region 170B may be implanted in P-well 150B. According to one or more examples, the P+ regions 170A and 170B may be made of p-type silicon. The P+ regions 170A and 170B may ultimately form the body terminal of the semiconductor device 100.

FIG. 2D shows an operation of implanting heavily doped n-type (N+) regions 160A and 160B within the respective P-wells 150A and 150B according to one or more examples. For example, N+ region 160A may be implanted within P-well 150A, and N+ region 160B may be implanted within P-well 150B. The N+ regions 160A and 160B may be made of n-type silicon, and may ultimately form the source terminal of the semiconductor device 100.

FIG. 2E shows an operation of adding a gate oxide layer 130 and poly-silicon layer 140 according to one or more examples. In FIG. 2E, a gate oxide layer 130 may be formed or grown on the silicon layer 120. According to one or more examples the gate oxide layer 130 may extend across the width of the silicon carbide substrate 110. By forming the gate oxide layer 130 on the silicon layer 120, as opposed on the silicon carbide substrate 110, carrier mobility may be improved, which may improve performance of the semiconductor device 100. As shown in FIG. 2E, a poly-silicon layer 140 may be formed on the gate oxide layer 130, which will ultimately form the gate terminal of the semiconductor device 100. Although poly-silicon is used in the example shown in FIG. 2E, metal or other suitable material may be used to form the gate terminal.

FIG. 2F shows an operation of adding contacts to form the terminals of the semiconductor device 100 according to one or more examples. For example, a contact 210 may be added to the poly-silicon layer 140 to form the gate terminal, contacts 220A and 220B may be added to the N+ regions 160A and 160B and the P+ regions 170A and 170B located on either side of the gate terminal to form the source terminal. For example, contact 220A is added to N+ region 160A and P+ region 170A, and contact 220B is added to N+ region 160B and P+ region 170B. In the example of FIG. 2F, the body terminal may be coupled to the source terminal. A contact 230 may also be added to the N+ region 180 at the opposite side of the silicon carbide substrate 110 to form the drain terminal.

Although the method 200 operations shown in FIGS. 2A-2F are shown in a particular order, the operations may be performed in a different order, and may include additional operations as one skilled in the art would understand.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A semiconductor device comprising:
a silicon carbide substrate;
a silicon layer formed at a first side of the silicon carbide substrate;
a gate oxide layer formed on the silicon layer;
a gate terminal formed on the gate oxide layer;
a drain terminal formed at a second side of the silicon carbide substrate opposite the first side; and
a source terminal formed at the first side of the silicon carbide substrate, and at opposite ends of the silicon layer.

2. The semiconductor device of claim 1, wherein the silicon carbide substrate is made of n-type silicon carbide.

3. The semiconductor device of claim 2, wherein the source terminal is made of n-type silicon.

4. The semiconductor device of claim 3, wherein the n-type silicon of the source terminal is more heavily doped than the n-type silicon carbide of the silicon carbide substrate.

5. The semiconductor device of claim 1, wherein the source terminal at least partially overlaps with the gate terminal.

6. The semiconductor device of claim 1, wherein the gate oxide layer has a thickness that is less than a thickness of the silicon layer.

7. The semiconductor device of claim 2, wherein the drain terminal is made of n-type silicon carbide.

8. The semiconductor device of claim 7, wherein the n-type silicon carbide of the drain terminal is more heavily doped than the n-type silicon carbide of the silicon carbide substrate.

9. The semiconductor device of claim 1 comprising:
first and second p-well regions disposed in the silicon carbide substrate at opposite ends of the silicon layer; and
first and second P+ regions within the first and second p-well regions, respectively;
wherein the source terminal is formed within the first and second p-well regions.

10. The semiconductor device of claim 9, wherein a portion of the silicon carbide substrate extends between the first and second p-well regions.

11. The semiconductor device of claim 9, wherein the first and second p-well regions are made of p-type silicon carbide.

12. The semiconductor device of claim 9, wherein the first and second P+ regions are made of p-type silicon.

13. The semiconductor device of claim 9 comprising:
a polysilicon layer on the gate oxide layer, wherein the gate terminal is formed on the polysilicon layer.

14. A method of manufacturing a semiconductor device, the method comprising:
forming a first N+ region at one side of a silicon carbide substrate for a drain terminal of the semiconductor device;
forming a silicon layer at an opposite side of the silicon carbide substrate that is opposite from the side at which the first N+ region is formed;
forming a gate oxide layer on the silicon layer, and a gate terminal on the gate oxide layer; and
forming second and third N+ regions on opposite sides of the silicon layer to form a source terminal.

15. The method of claim 14, comprising:
forming first and second p-well regions in the silicon carbide substrate at opposite ends of the silicon layer;
forming first and second P+ regions within the first and second p-well regions;
wherein the second and third N+ regions are respectively formed within the first and second p-well regions.

16. The method of claim 15, wherein the first and second p-well regions are made of p-type silicon carbide, and the second and third N+ regions are made of n-type silicon.

17. The method of claim 16, wherein the first N+ region is made of n-type silicon carbide.

18. The method of claim 14, comprising forming a polysilicon layer on the gate oxide layer, wherein the gate terminal is formed on the polysilicon layer.

19. The method of claim 14, wherein the second and third N+ regions at least partially overlap the gate oxide layer.

20. The method of claim 15, wherein a portion of the silicon carbide substrate extends between the first and second p-well regions.
